(19) United States
(12) Patent Application Publication
(10) Pub. No.: US 2026/0076096 A1
(43) Pub. Date: Mar. 12, 2026

(54) DOUBLE MAGNETIC TUNNEL JUNCTION MAGNETORESISTIVE MEMORY DEVICE AND METHOD OF MAKING THEREOF

(71) Applicant: Sandisk Technologies, Inc., Milpitas, CA (US)

(72) Inventors: Wonjoon JUNG, San Jose, CA (US); Goran MIHAJLOVIC, San Jose, CA (US); Rajesh CHOPDEKAR, San Jose, CA (US); Nathan FRANKLIN, Belmont, CA (US)

(21) Appl. No.: 18/882,112

(22) Filed: Sep. 11, 2024

(51) Int. Cl. H10N 50/10; H10B 61/00; H10N 50/01; H10N 50/85

(52) U.S. Cl. CPC H10N 50/10; H10B 61/10; H10N 50/01; H10N 50/85

(57) ABSTRACT

A memory device includes a magnetoresistive memory cell which contains a first terminal electrode, a second terminal electrode, and a double magnetic tunnel junction located between the first terminal electrode and the second terminal electrode. The double magnetic tunnel junction includes, from bottom to top, a bottom synthetic antiferromagnet (SAF) structure including a barrier-contacting bottom ferromagnetic layer, a first tunneling barrier layer, a common free layer, a second tunneling barrier layer, and a top SAF structure including a barrier-contacting top ferromagnetic layer in antiparallel alignment with the barrier-contacting bottom ferromagnetic layer. The bottom SAF structure is different from the top SAF structure.

### FIELD

The present disclosure relates generally to the field of magnetic memory devices and specifically to a double magnetic tunnel junction magnetoresistive memory device and method of making thereof.

### BACKGROUND

Spin-transfer torque (STT) refers to an effect in which the orientation of a magnetic layer in a magnetic junction structure or spin valve is modified by a spin-polarized current. Generally, electric current is unpolarized, with electrons having random spin orientations. A spin-polarized current is one in which electrons have a net non-zero spin due to a preferential spin orientation distribution. A spin-polarized current can be generated by passing electrical current through a magnetic polarizer layer. When the spin-polarized current flows through a free layer of a magnetic junction structure or a spin valve, the electrons in the spin-polarized current can transfer at least some of their angular momentum to the free layer, thereby producing a torque on the magnetization of the free layer. When a sufficient amount of spin-polarized current passes through the free layer, spin-transfer torque can be employed to flip the orientation of the spin (e.g., change the magnetization) in the free layer. A resistance differential of a magnetic junction structure between different magnetization states of the free layer can be employed to store data within the magnetoresistive random access memory (MRAM) cell depending on whether the magnetization of the free layer is parallel or antiparallel to the magnetization of the polarizer layer, also known as a reference layer.

### SUMMARY

According to an aspect of the present disclosure, a memory device includes a magnetoresistive memory cell which contains a first terminal electrode, a second terminal electrode, and a double magnetic tunnel junction located between the first terminal electrode and the second terminal electrode. The double magnetic tunnel junction includes, from bottom to top, a bottom synthetic antiferromagnet (SAF) structure including a barrier-contacting bottom ferromagnetic layer, a first tunneling barrier layer, a common free layer, a second tunneling barrier layer, and a top SAF structure including a barrier-contacting top ferromagnetic layer in antiparallel alignment with the barrier-contacting bottom ferromagnetic layer. The bottom SAF structure is different from the top SAF structure.

According to another aspect of the present disclosure, a method of making a memory device includes forming a first terminal electrode over a substrate; forming a double magnetic tunnel junction over the first terminal electrode by forming a bottom synthetic antiferromagnet (SAF) structure including a barrier-contacting bottom ferromagnetic layer over the first terminal electrode, forming a first tunneling barrier layer over the bottom SAF structure, forming a common free layer over the first tunneling barrier layer, forming a second tunneling barrier layer over common free layer, and forming a top SAF structure including a barrier-contacting top ferromagnetic layer over the second common free layer, wherein the barrier-contacting top ferromagnetic layer is formed in antiparallel alignment with the barrier-contacting bottom ferromagnetic layer without applying an external magnetic field; and forming a second terminal electrode over the double magnetic tunnel junction.

### BRIEF DESCRIPTION OF THE DRAWINGS

FIG. 1 is a schematic diagram of an exemplary circuit including an array of two-terminal magnetoresistive memory cells according to an embodiment of the present disclosure.

FIG. 2 illustrates a first exemplary magnetoresistive memory cell according to a first embodiment of the present disclosure.

FIG. 3 illustrates a second exemplary magnetoresistive memory cell according to a second embodiment of the present disclosure.

### DETAILED DESCRIPTION

It is desirable to reduce the MRAM switching current in MRAM crosspoint arrays to ensure effective and fast writing of the data. However, prior art MRAM devices with reduced switching current suffered from sharp rise of snapback current during ovonic threshold switch (OTS) selector element turn-on, which can disturb the stored data (i.e., read disturb) and increase the bit error rate. Furthermore, in addition to the above read disturb problem, some prior art double magnetic tunnel junction stacks can suffer from back hopping due to weak reference layer pinning and unfavorable magnetostatic fields. Often, these stacks require complicated magnetic field settings to achieve the desired anti-parallel configuration of the reference layers, adding to the complexity and potential reliability issues of MRAM devices.

The embodiments of the present disclosure are directed to a double magnetic tunnel junction magnetoresistive memory devices, the various aspects of which are described below. The embodiment devices can provide a significant reduction in switching current, minimized snapback current during OTS turn-on, increased spin-transfer torque efficiency, higher write margin gain, improved data retention and reduced read disturb and elimination of back hopping. The embodiment double magnetic tunnel junction magnetoresistive memory devices include two reference layers whose magnetizations are oriented anti-parallel at remanence with no additional field setting procedures, and a common free layer located between the two reference layers. The common free layer has a high moment, strong perpendicular anisotropy, and low damping.

The drawings are not drawn to scale. Multiple instances of an element may be duplicated where a single instance of the element is illustrated, unless absence of duplication of elements is expressly described or clearly indicated otherwise. Same reference numerals refer to the same element or to a similar element. Elements having the same reference numerals are presumed to have the same material composition unless expressly stated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, an “in-process” structure or a “transient” structure refers to a structure that is subsequently modified.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” refers to a layer that has a predominant direction of extension, i.e., having a direction along which the layer extends the most. As used herein, the thickness of a material layer that is thinner than the thickness of a monolayer (and thus, does not form a single continuous material layer without openings) is measured by the ratio of an integrated surface density of the material layer (which may be measured, for example, by secondary ion mass spectroscopy by counting the number of atoms that are present per unit area during a sputtering process) divided by the bulk density of the material in the material layer.

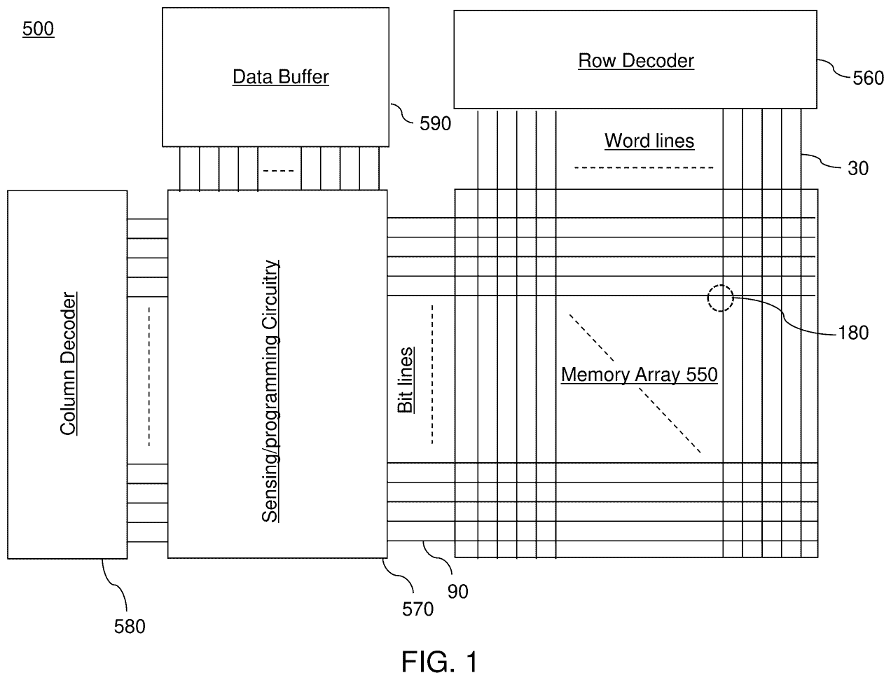

Referring to FIG. 1, a schematic diagram is shown for an exemplary circuit including an array of magnetoresistive memory cells 180 according to the first and second embodiments of the present disclosure. The exemplary circuit may comprise a random access memory (RAM) device 500 including the magnetoresistive memory cells 180 in a cross-point array configuration. As used herein, a “random access memory” (RAM) refers to a memory device containing memory cells that allow random access, e.g., access to any selected memory cell upon a command for reading the contents of the selected memory cell. According to an aspect of the present disclosure, the magnetoresistive memory cells 180 comprise a series connection of a double magnetoresistive tunnel junction device and a selector element.

The RAM device 500 includes a memory array region 550 including word lines 30 and bit lines 90. In one embodiment, a first terminal electrode of each magnetoresistive memory cells 180 can be electrically connected to one of the word lines 30, and a second terminal electrode of each magnetoresistive memory cells 180 can be electrically connected to one of the bit lines 90. Alternatively, a first terminal electrode of each magnetoresistive memory cells 180 can be electrically connected to one of the bit lines 90, and a second terminal electrode of each magnetoresistive memory cells 180 can be electrically connected to one of the word lines 30. The terms “bit line” and “word line” are arbitrary names that are assigned to various conductive lines for clarity, but should not be considered limiting.

In an illustrative example, the RAM device 500 may also contain a row decoder 560 connected to the word lines 30, and a sense amplifier circuitry and a programming circuitry connected to the programming bit lines 90. In some embodiments, the sense amplifier circuitry and the programming circuitry are collectively referred to as a sensing/programming circuitry 570. A column decoder 580 and a data seed 590 can be connected to the sensing/programming circuitry 570. A row decoder 560 can be connected to the word lines 30. Multiple instances of the magnetoresistive memory cells 180 are provided in an array configuration that forms the RAM device 500. It should be noted that the location and interconnection of elements are schematic and the elements may be arranged in a different configuration. Further, a magnetoresistive memory cells 180 may be manufactured as a discrete device, i.e., a single isolated device.

Each magnetoresistive memory cells 180 includes a spin-transfer torque (STT) double magnetic tunnel junction (DMTJ) structure having at least two different resistive states depending on the alignment of the magnetization direction of the free layer relative to the reference layers. The double junction magnetic tunnel junction structure within each magnetoresistive memory cells 180 is provided between a first terminal electrode and a second terminal electrode.

One parameter used to evaluate performance of a magnetic tunnel junction device is the thermal stability factor Δ. The thermal stability factor Δ quantifies the stability of the magnetic state of a memory bit against thermal fluctuations. Mathematically, it is defined as Δ=E_{B}/(k_{B}T) where E_{B} is the energy barrier that separates the two stable magnetization states, k_{B} is the Boltzmann constant, and T is the absolute temperature. A higher Δ indicates greater data retention, meaning the stored magnetic state (i.e., the magnetization direction of the common free layer) is more resistant to spontaneous flipping due to thermal energy. The higher the thermal stability factor Δ, the more stable the magnetic state is, making it less likely that the stored data bit will change due to thermal noise.

Another parameter for evaluating performance of a magnetic tunnel junction device is the critical current density J_{C0}. The critical current density J_{C0} is the current density required to switch the magnetization of a magnetic tunnel junction (MTJ) by spin-transfer torque. The critical current density J_{C0} indicates the minimum current density necessary to overcome the energy barrier E_{B} and to induce a transition from one magnetic state to another (i.e., to switch the magnetization direction of the free layer). Lowering the critical current density J_{C0} is desirable because a low critical current density J_{C0} reduces the power required for writing data in MRAM devices, thereby improving energy efficiency and reducing heat generation during operation.

The overall performance of a magnetic tunnel junction device can be measured by the ratio of the thermal stability factor Δ to the critical current density J_{C0}, i.e., Δ/J_{C0}, which may be used as a figure-of-merit for measuring performance of MRAM devices. Generally, the MRAM switching current can be significantly reduced by employing a double magnetic tunnel junction (MTJ) design. The low switching current of double MTJ is beneficial as it improves writing of high-density crosspoint array cells. However, it can also be problematic in magnetoresistive random access memory-ovonic threshold switch (MRAM-OTS) crosspoint arrays because the sharp rise of snapback current during OTS turn-on can disturb the stored data and increase the bit error rate.

In addition to snapback disturbance, the double MTJ stacks can be prone to other issues, such as back hopping and the use of an external magnetic field setting for initializing the magnetization directions of two reference layers. Back hopping can occur due to weak reference layer pinning and unfavorable magnetostatic fields.

The double junction (i.e., dual junction) magnetoresistive memory cell 180 of embodiments of the present disclosure can be written at a reduced the critical current density J_{C0} and has improved stability due to a reduction in the snapback disturbance in the MRAM-OTS crosspoint array configuration. In one embodiment, the double junction magnetoresistive memory cell 180 provides substantial reduction in the switching (i.e., writing) current (I_{C}) at 50 ns (which is the timescale of write operations), while maintaining a high switching current at around 1 ns or less (which is the timescale of snapback disturbance).

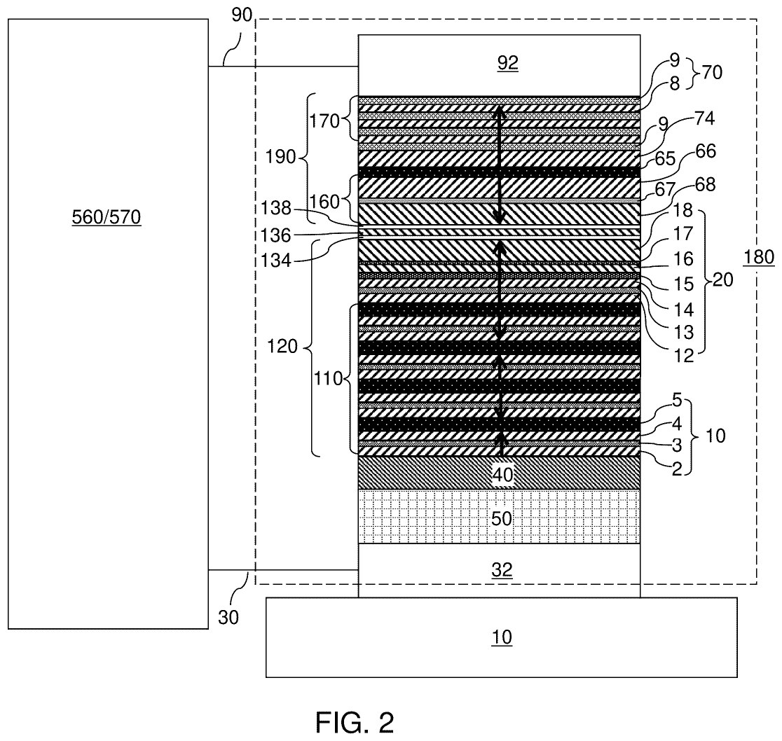

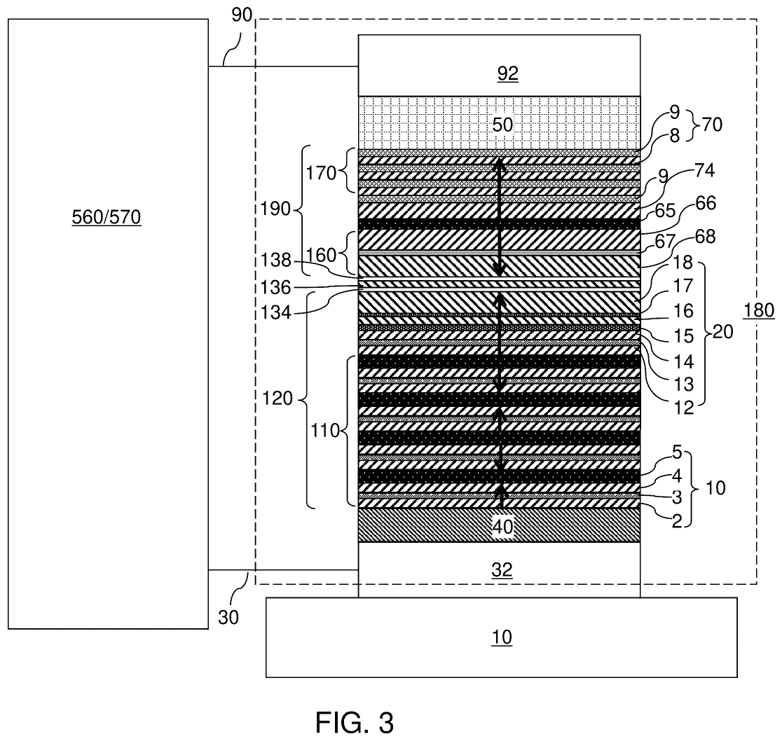

Referring to FIGS. 2 and 3, exemplary configurations for the double junction magnetoresistive memory cell 180 of the first and second embodiments of the present disclosure are illustrated. FIG. 2 illustrates a first exemplary configuration of the first embodiment in which a selector element 50 underlies a magnetoresistive layer stack (120, 134, 136, 138, 190). FIG. 3 illustrates a second exemplary configuration of the second embodiment in which a selector element 50 overlies a magnetoresistive layer stack (120, 134, 136, 138, 190). Generally, one of a word lines 30 and a bit line 90 can be electrically connected to a first terminal electrode 32, and another of the word line 30 and the bit line 90 can be electrically connected to a second terminal electrode 92. A metal seed layer 40 including a material that sets a preferential crystallization direction can be provided below the magnetoresistive layer stack (120, 134, 136, 138, 190). For example, the metal seed layer 40 may comprise a tungsten layer that sets the <001>direction as the preferential crystallographic direction that is aligned along the vertical direction for the metallic layers that are formed thereupon. The thickness of the metal seed layer 40 may be in a range from 2 nm to 10 nm.

The selector element 50 may comprise any suitable ovonic threshold switch (OTS) material, which exhibits non-linear electrical behavior. As used herein, an ovonic threshold switch material refers to a material that displays a non-linear resistivity curve under an applied external bias voltage such that the resistivity of the material decreases with the magnitude of the applied external bias voltage. In other words, the ovonic threshold switch material is non-Ohmic, and becomes more conductive under a higher external bias voltage than under a lower external bias voltage, and reverts back to a high resistivity state when not subjected to a voltage above a critical holding voltage.

In one embodiment, the ovonic threshold switching material may comprise a chalcogen-containing ovonic threshold switching material layer which does not crystallize in the low resistivity state. Thus, the ovonic threshold switching material (OTS material) can be non-crystalline (for example, amorphous) in the high resistivity state, and can remain non-crystalline (for example, remain amorphous) in a low resistivity state. In one embodiment, the ovonic threshold switching material can comprise an amorphous chalcogenide material, such as a GeSeAs alloy, a GeSeAsTe alloy, a GeTeAs alloy, a GeSeTe alloy, a GeSe alloy, a SeAs alloy, an AsTe alloy, a GeTe alloy, a SiTe alloy, a SiAsTe alloy, or SiAsSe alloy. The chalcogenide material may be undoped or doped with at least one of N, O, C, P, Ge, As, Te, Se, In, or Si. The thickness of the ovonic threshold switching material can be, for example, in a range from 1 nm to 50 nm, such as from 5 nm to 25 nm, although lesser and greater thicknesses can also be employed.

The selector element 50 may optionally include a lower metallic plate (e.g. a metal or metal nitride plate) and/or a lower carbon-based material plate underneath a portion of the ovonic threshold switch material. Further, the selector element 50 may optionally includer an upper metallic plate and/or an upper carbon-based material plate above the portion of the ovonic threshold switch material.

The magnetoresistive memory cell 180 also comprises a first terminal electrode 32, a second terminal electrode 92, and a magnetoresistive layer stack (120, 134, 136, 138, 190) located above or below the selector element 50, as shown in FIGS. 2 and 3, respectively. The magnetoresistive layer stack (120, 134, 136, 138, 190) of the embodiments shown in FIGS. 2 and 3, includes a first synthetic antiferromagnet (SAF) structure 120 including a first barrier-contacting ferromagnetic layer 18, a second SAF structure 190 including a second barrier-contacting ferromagnetic layer 68, a common ferromagnetic free layer 136, a first tunneling barrier layer 134 located between the first barrier-contacting ferromagnetic layer 18 and the free layer 136, and second tunneling barrier layer 138 located between the second barrier-contacting ferromagnetic layer 68 and the free layer 136. As used herein, a “barrier-contacting” layer refers to a layer that is in direct contact with a tunneling barrier layer. The first barrier-contacting ferromagnetic layer 18 is in antiparallel alignment with the second barrier-contacting ferromagnetic layer 68. In other words, the magnetization direction of the first barrier-contacting ferromagnetic layer 18 is antiparallel to the magnetization direction of the second barrier-contacting ferromagnetic layer 68.

In one embodiment, the first SAF structure 120 comprises a bottom SAF structure, the first barrier-contacting ferromagnetic layer 18 comprises a barrier-contacting bottom ferromagnetic layer, the second SAF structure 190 comprises a top SAF structure, and the second barrier-contacting ferromagnetic layer 68 comprises a barrier-contacting top ferromagnetic layer. In this case, the magnetoresistive layer stack (120, 134, 136, 138, 190) includes from bottom to top, the bottom SAF structure 120 including the barrier-contacting bottom ferromagnetic layer 18, the first tunneling barrier layer 134 in contact with the barrier-contacting bottom ferromagnetic layer 18, the free layer 136 in contact with the first tunneling barrier layer 134, the second tunneling barrier layer 138 in contact with the free layer 136, and the top SAF structure 190 including the barrier-contacting top ferromagnetic layer 68 in contact with the second tunneling barrier layer 138. The barrier-contacting top ferromagnetic layer 68 is in antiparallel alignment with the barrier-contacting bottom ferromagnetic layer 18.

The magnetoresistive layer stack (120, 134, 136, 138, 190) includes a double magnetic tunnel junction structure (18, 134, 136, 138, 68). The double magnetic tunnel junction structure (18, 134, 136, 138, 68) comprises, from bottom to top, the barrier-contacting bottom ferromagnetic layer 18, the first tunneling barrier layer 134, the free layer 136, the second tunneling barrier layer 138, and the barrier-contacting top ferromagnetic layer 68.

In an alternative embodiment, the first SAF structure 120 comprises a top SAF structure, the first barrier-contacting ferromagnetic layer 18 comprises a barrier-contacting top ferromagnetic layer, the second SAF structure 190 comprises a bottom SAF structure, and the second barrier-contacting ferromagnetic layer 68 comprises a barrier-contacting bottom ferromagnetic layer. In this alternative embodiment, the layers of each of the SAF structures (120, 190) are stacked in opposite order.

Each of the first tunneling barrier layer 134 and the second tunneling barrier layer 138 comprises a dielectric material, such as magnesium oxide or a magnesium aluminum oxide spinel. The thickness of each of the first tunneling barrier layer 134 and the second tunneling barrier layer 138 may be in a range from 0.8 nm to 2 nm, such as from 1.0 nm to 1.6 nm, although lesser and greater thicknesses may also be employed.

Because the magnetization direction of the barrier-contacting top ferromagnetic layer 68 is antiparallel to the magnetization direction of the barrier-contacting bottom ferromagnetic layer 18, the free layer 136 is in parallel alignment with one of the barrier-contacting top ferromagnetic layer 68 and the barrier-contacting bottom ferromagnetic layer 18, and is in antiparallel alignment with another of the barrier-contacting top ferromagnetic layer 68 and the barrier-contacting bottom ferromagnetic layer 18 at all times. For the first magnetic tunnel junction including the barrier-contacting bottom ferromagnetic layer 18, the first tunneling barrier layer 134, and the free layer 136, a parallel alignment between the magnetization directions of the barrier-contacting bottom ferromagnetic layer 18 and the free layer 136 can provide a first parallel tunneling resistance R₁ₚ, and an antiparallel alignment between the magnetization directions of the barrier-contacting bottom ferromagnetic layer 18 and the free layer 136 can provide a first antiparallel tunneling resistance R₁ₐₚ. For the second magnetic tunnel junction including the free layer 136, the second tunneling barrier layer 138, and the barrier-contacting top ferromagnetic layer 68, a parallel alignment between the magnetization directions of the free layer 136 and the barrier-contacting top ferromagnetic layer 68 can provide a second parallel tunneling resistance R₂ₚ, and an antiparallel alignment between the magnetization directions of the free layer 136 and the barrier-contacting top ferromagnetic layer 68 can provide a second antiparallel tunneling resistance R₂ₐₚ.

In a first programmed state in which the magnetization direction of the free layer 136 is parallel to the magnetization direction of the barrier-contacting bottom ferromagnetic layer 18 and is antiparallel to the magnetization direction of the barrier-contacting top ferromagnetic layer 68, the total resistance of the double magnetitic tunnel junction structure is the sum of the first parallel tunneling resistance R₁ₚ and the second antiparallel tunneling resistance R₂ₐₚ, i.e., R₁ₚ+R₂ₐₚ. In a second programmed state in which the magnetization direction of the free layer 136 is antiparallel to the magnetization direction of the barrier-contacting bottom ferromagnetic layer 18 and is parallel to the magnetization direction of the barrier-contacting top ferromagnetic layer 68, the total resistance of the double magnetitic tunnel junction structure is the sum of the first antiparallel tunneling resistance R₁ₐₚ and the second parallel tunneling resistance R₂ₚ, i.e., R₁ₐₚ+R₂ₚ.

In one embodiment, the materials and/or the thicknesses of the first tunneling barrier layer 134 and the second tunneling barrier layer 138 may be different from each other such that the resistance of a first magnetic tunnel junction (18, 134, 136) is different than the resistance of the second magnetic tunnel junction (68, 138, 136). The double magnetic tunnel junction structure (18, 134, 136, 138, 68) can have two magnetic configurations, which include a first magnetic configuration in which the first magnetic tunnel junction (18, 134, 136) is in a parallel state and the second magnetic tunnel junction (68, 138, 136) is in an antiparallel state; and a second magnetic configuration in which the first magnetic tunnel junction (18, 134, 136) is in an antiparallel state and the second magnetic tunnel junction (68, 138, 136) is in a parallel state. In order for the two magnetic configurations to be electrically distinguishable, the total tunneling resistance of the first magnetic configuration should be different from the total tunneling resistance of the second magnetic configuration. In this case, the first sum of the first parallel tunneling resistance R₁ₚ and the second antiparallel tunneling resistance R₂ₐₚ does not equal the second sum of the first antiparallel tunneling resistance R₁ₐₚ and the second parallel tunneling resistance R₂ₚ, i.e., R₁ₚ+R₂ₐₚ≠R₁ₐₚ+R₂ₚ. Preferably, the greater of the first sum and the second sum is in a range from 120% to 1,000%, such as from 150% to 500%, and/or from 200% to 400%, of the lesser of the first sum and the second sum. In other words, the greater one of the two total tunnelling resistances of the two magnetic configurations is in a range from 120% to 1,000%, such as from 150% to 500%, and/or from 200% to 400%, of the lesser one of the total tunneling resistances of the two magnetic configurations.

In one embodiment, the barrier-contacting bottom ferromagnetic layer 18, the barrier-contacting top ferromagnetic layer 68 and the free layer 136 comprise the same or different ferromagnetic material. In one embodiment, the barrier-contacting bottom ferromagnetic layer 18, the barrier-contacting top ferromagnetic layer 68 and the free layer 136 comprise CoFeB, CoFe, Co, Ni, NiFe, or a combination thereof.

For example, the barrier-contacting bottom ferromagnetic layer 18 may have a thickness in a range from 0.5 nm to 3 nm, such as from 1 nm to 2.5 nm, the barrier-contacting top ferromagnetic layer 68 may have a thickness in a range from 0.5 nm to 3 nm, such as from 1 nm to 2.5 nm, and the free layer 136 may have a thickness in a range from 0.5 nm to 3 nm, such as from 1 nm to 2.5 nm.

According to an aspect of the present disclosure, the antiparallel alignment of the magnetization directions of the barrier-contacting bottom ferromagnetic layer 18 and the barrier-contacting top ferromagnetic layer 68 is achieved by controlling the magnetic properties of various component layers within the bottom SAF structure 120 and the top SAF structure 190. In one embodiment, the magnetization of the barrier-contacting bottom ferromagnetic layer 18 points upward and the magnetization of the barrier-contacting top ferromagnetic layer 68 points downward.

The alignment of the magnetization directions of the barrier-contacting bottom ferromagnetic layer 18 and the barrier-contacting top ferromagnetic layer 68 is governed by the interaction between Zeeman energy (Z) and exchange coupling energy (Jₑₓ) through an antiferromagnetic coupling layer (5, 65). The Zeeman energy arises from the application of an external magnetic field, and tends to align the magnetization directions of two adjacent ferromagnetic material layers in the same direction as the applied magnetic field. In contrast, the exchange coupling energy through an antiferromagnetic coupling layer (5, 65) tends to align the magnetization directions of two adjacent ferromagnetic material layers in in opposite directions, thereby promoting an antiparallel configuration.

In a non-limiting illustrative example, the barrier-contacting bottom ferromagnetic layer 18 may comprise CoFeB and may have a thickness in a range from 0.5 nm to 3 nm, the barrier-contacting top ferromagnetic layer 68 may comprise CoFeB and may have a thickness in a range from 0.5 nm to 3 nm, and the free layer 136 may comprise CoFeB and may have a thickness in a range from 1 nm to 3 nm.

Generally, the bottom SAF structure 120 and the top SAF structure 190 are configured in a manner that assists the antiparallel alignment between the magnetization directions of the barrier-contacting bottom ferromagnetic layer 18 and the barrier-contacting top ferromagnetic layer 68. In an illustrative example, the bottom SAF structure 120 may comprise, from bottom to top, a bottom superlattice 110 and a bottom reference layer stack 20. The barrier-contacting bottom ferromagnetic layer 18 can be the topmost ferromagnetic material layer within the bottom reference layer stack 20.

In one embodiment, the bottom superlattice 110 may comprise a periodic repetition of a unit layer stack 10 that includes at least one ferromagnetic component layer (2, 4) and an antiferromagnetic coupling layer 5. For example, the unit layer stack 10 may comprise, from bottom to top, a first ferromagnetic component layer 2, a nonmagnetic metal spacer layer 3, a second ferromagnetic component layer 4, and an antiferromagnetic coupling layer 5.

The nonmagnetic metal spacer layer 3 induces perpendicular magnetic anisotropy (PMA) in neighboring ferromagnetic material layers (i.e., in an underlying first ferromagnetic component layer 2 and in an overlying second ferromagnetic component layer 4). The perpendicular magnetic anisotropy provided by the nonmagnetic metal spacer layer 3 aligns the magnetic moments in the first ferromagnetic component layer 2 and the second ferromagnetic component layer 4 in a parallel orientation in each unit layer stack 10 along a vertical direction, i.e., along a direction that is perpendicular to the predominant surfaces of the nonmagnetic metal spacer layer 3 (which are the top horizontal surface and the bottom horizontal surface).

Each second ferromagnetic component layer 4 can be antiferromagnetically coupled to the first ferromagnetic component layer 2 of an overlying unit layer stack 10 through an antiferromagnetic coupling layer 5. The antiferromagnetic coupling layer 5 facilitates antiparallel alignment of magnetization directions between a neighboring pair of ferromagnetic material layers, i.e., between an underlying second ferromagnetic component layer 4 and an overlying first ferromagnetic component layer 2.

In a non-limiting illustrative example, the first ferromagnetic component layers 2 and the second ferromagnetic component layers 4 may comprise cobalt layers having a respective thickness in a range from 0.2 nm to 1 nm, the nonmagnetic metal spacer layers 3 may comprise platinum layers having a respective thickness in a range from 0.1 nm to 1 nm, and the antiferromagnetic coupling layers 5 may comprise an iridium layers or ruthenium layers having a respective thickness in a range from 0.4 nm to 1 nm. For example, the antiferromagnetic coupling layers 5 may comprise ruthenium layers having a thickness between 0.3 nm and 1 nm, or may comprise iridium layers having a thickness in a range from 0.4 nm to 0.6 nm. There may be two to six unit layer stacks 10, such as four unit layer stacks 10 in the bottom superlattice 110.

The bottom reference layer stack 20 comprises various ferromagnetic material layers and nonmagnetic metal spacer layers, and are designed to assist the antiparallel alignment of the magnetization directions of the barrier-contacting bottom ferromagnetic layer 18 and the barrier-contacting top ferromagnetic layer 68. The topmost layer of the bottom reference layer stack 20 is the barrier-contacting bottom ferromagnetic layer 18. In a non-limiting illustrative example, the bottom reference layer stack 20 may comprise, from top to bottom, the barrier-contacting bottom ferromagnetic layer 18, a first nonmagnetic metal spacer layer 17, a first proximal bottom ferromagnetic layer 16, a second nonmagnetic metal spacer layer 15, a second proximal bottom ferromagnetic layer 14, a third nonmagnetic metal spacer layer 13, and a third proximal bottom ferromagnetic layer 12.

Generally, at least one proximal bottom ferromagnetic layer (12, 14, 16) can be provided between the bottom superlattice 110 and the barrier-contacting bottom ferromagnetic layer 18. In one embodiment, a plurality of proximal bottom ferromagnetic layers (12, 14, 16) are located between the barrier-contacting bottom ferromagnetic layer 18 and the bottom superlattice 110.

In one embodiment, the barrier-contacting bottom ferromagnetic layer 18 and the first proximal bottom ferromagnetic layer 16 contact the first nonmagnetic metal spacer 17, and are spaced from each other by the first nonmagnetic metal spacer layer 17. In a non-limiting illustrative example, the first nonmagnetic metal spacer layer 17 may comprise a tungsten layer having a thickness in a range from 0.02 nm to 0.2 nm; the first proximal bottom ferromagnetic layer 16 may comprise the first ferromagnetic material (such as CoFeB) and may have a thickness (e.g., a thickness in a range from 0.2 nm to 1.0 nm; the second nonmagnetic metal spacer layer 15 may comprise a tungsten layer having a thickness in a range from 0.05 nm to 0.3 nm; the second and third proximal bottom ferromagnetic layers 12 and 14 may comprise respective cobalt layers having a thickness in a range from 0.2 nm to 1.0 nm; and the third nonmagnetic metal spacer layer 13 may comprise a platinum layer having a thickness in a range from 0.1 nm to 1 nm. The first and second nonmagnetic metal spacer layers (17, 15) may function as texture breaking layers which disrupt the crystallographic structure of overlying ferromagnetic layers and which also gather boron from CoFeB during annealing of the MRAM device. They also dilute the moment of ferromagnetic layers and make it easier for the ferromagnetic layers to have a perpendicular magnetic orientation. Within the bottom SAF structure 120, each bottom antiferromagnetic coupling layer 5 provides antiferromagnetic alignment between vertically neighboring pairs of ferromagnetic material layers. Within the bottom SAF structure 120, the magnetization directions of ferromagnetic material layers change along the vertical direction only across the bottom antiferromagnetic coupling layers 5. In other words, the magnetization directions of ferromagnetic material layers are antiparallel across a bottom antiferromagnetic coupling layer 5 in the bottom SAF structure 120.

The top SAF structure 190 may comprise, from bottom to top, a top reference layer stack 160, a top antiferromagnetic coupling layer 65, an topside ferromagnetic layer 74, a nonmagnetic metal spacer layer 9, and a top superlattice 170. In one embodiment, the top superlattice 170 may comprise a periodic repetition of a unit layer stack 70 that includes at least one ferromagnetic component layer 8 and a nonmagnetic metal spacer layer 9. For example, the unit layer stack 70 may comprise, from bottom to top, a ferromagnetic component layer 8 and a nonmagnetic metal spacer layer 9. The ferromagnetic component layer 8 may comprise a cobalt layer having a thickness between 0.2 nm and 1.3 nm. The nonmagnetic metal spacer layer 9 may comprise a platinum layer having a thickness between 0.1 nm and 1.0 nm. The top superlattice 170 may comprise two to five unit layer stacks 70, such as three unit layer stacks 70. The magnetization direction of each ferromagnetic component layer 8 is parallel to the magnetization direction of the topside ferromagnetic layer 74. In one embodiment, the top superlattice 170 is free of any antiferromagnetic coupling layer.

The top reference layer stack 160 comprises the barrier-contacting top ferromagnetic layer 68 as the bottommost ferromagnetic material layer, and further comprises a proximal top ferromagnetic layer 66 that overlies the barrier-contacting top ferromagnetic layer 68. The proximal top ferromagnetic layer 66 is most proximal to the barrier-contacting top ferromagnetic layer 68 among all ferromagnetic material layers that overlie the barrier-contacting top ferromagnetic layer 68.

In one embodiment, the barrier-contacting top ferromagnetic layer 68 comprises a first ferromagnetic material, such as CoFeB, and the proximal top ferromagnetic layer 66 comprises a different, second ferromagnetic material, such as Co.

The barrier-contacting top ferromagnetic layer 68 may have a thickness between 0.5 nm and 3 nm. The proximal top ferromagnetic layer 66 may have a thickness between 0.2 nm and 1.0 nm. The topside ferromagnetic layer 74 may have a thickness between 0.2 nm and 1.0 nm. Thus, the barrier-contacting top ferromagnetic layer 68 may comprise a different ferromagnetic material than the proximal top ferromagnetic layer 66 and the topside ferromagnetic layer 74.

Generally, the proximal top ferromagnetic layer 66 can be located between the top superlattice 170 and the barrier-contacting top ferromagnetic layer 68. In one embodiment, the barrier-contacting top ferromagnetic layer 68 and the proximal top ferromagnetic layer 66 contact the first nonmagnetic metal spacer 67, and are spaced from each other by the first nonmagnetic metal spacer 67. The first nonmagnetic metal spacer 67 may comprise a tungsten texture breaking layer having a thickness between 0.05 nm and 0.3 nm.

In one embodiment, the proximal top ferromagnetic layer 66 and the topside ferromagnetic layer 74 contact the top antiferromagnetic coupling layer 65, and are spaced from each other by the top antiferromagnetic coupling layer 65. The top antiferromagnetic coupling layer 65 may comprise iridium or ruthenium, and may have a thickness in a range from 0.3 nm to 1.0 nm. For example, the top antiferromagnetic coupling layer 65 may comprise ruthenium having a thickness in a range from 0.3 nm to 1 nm, or may comprise iridium having a thickness in a range from 0.4 nm to 0.6 nm. In one embodiment, the top antiferromagnetic coupling layer 65 comprises a different material the bottom antiferromagnetic coupling layers 5. The topside ferromagnetic layer 74 is spaced from the top superlattice 170 by an addition nonmagnetic metal spacer layer 9.

In one embodiment, the top reference layer stack 160 comprises a proximal top ferromagnetic layer 66 having the same magnetization direction as the magnetization direction of a barrier-containing top ferromagnetic layer 68. The proximal top ferromagnetic layer 66 and the barrier-contacting top ferromagnetic layer 68 have parallel magnetization direction. The magnetization directions of the topside ferromagnetic layer 74 and the ferromagnetic layers 8 in the top superlattice 170 are parallel to each other. The proximal top ferromagnetic layer 66 and the barrier-contacting top ferromagnetic layer 68 are antiferromagnetically coupled to, and have antiparallel magnetization directions relative to the topside ferromagnetic layer 74 and the ferromagnetic component layers 8 of top superlattice 170. In one embodiment, the bottom reference layer stack 20 comprises a first proximal bottom ferromagnetic layer 16, a second proximal bottom ferromagnetic layer 14, and a third proximal bottom ferromagnetic layer 12 that have the same magnetization directions as the magnetization direction of the barrier-contacting bottom ferromagnetic layer 18. In other words, all ferromagnetic material layers in the reference layer stack 20 have the same magnetization direction. Each of the antiferromagnetic coupling layers (5, 65) provides antiparallel alignment between the ferromagnetic material layers that are vertically spaced by the respective one of the antiferromagnetic coupling layers (5, 65). The magnetization of the top reference layer stack 160 is antiparallel to the magnetization of the bottom reference layer stack 20.

Generally, the magnetization direction of all ferromagnetic material layers in the magnetoresistive layer stack (120, 134, 136, 138, 190) can be aligned in a configuration that minimizes the total magnetic energy of the magnetoresistive layer stack (120, 134, 136, 138, 190). The free layer 136, the barrier-contacting bottom ferromagnetic layer 18, the barrier-contacting top ferromagnetic layer 68, the bottom reference layer stack 20, and the top reference layer stack 160 are configured such that the total magnetic energy of the magnetoresistive layer stack (120, 134, 136, 138, 190) is minimized when the magnetization directions of the barrier-contacting bottom ferromagnetic layer 18 and the barrier-contacting top ferromagnetic layer 68 are antiparallel to each other. The magnetoresistive layer stack (120, 134, 136, 138, 190) provides two stable magnetization directions for the free layer 136, i.e., the upward direction and the downward direction. Both of the two stable magnetization directions for the free layer 136 correspond to the local minima in the total magnetic energy of the magnetoresistive layer stack (120, 134, 136, 138, 190).

According to an aspect of the present disclosure, the magnetization direction of the top reference layer stack 160 is antiparallel relative to the magnetization direction of the bottom reference layer stack 20 by providing the following two conditions. The first condition is that the magnetic moment of all ferromagnetic layers (68, 66) in the top reference layer stack 160 is less than the magnetic moment of all ferromagnetic layers (74, 8) that overlie the top antiferromagnetic coupling layer 65. In other words, the magnetic moment of the barrier-contacting bottom ferromagnetic layer 68 and the proximal top magnetization layer 66 has a lesser magnitude and an antiparallel direction relative to the magnetic moment of the topside ferromagnetic layer 74 and the ferromagnetic component layers 8.

The second condition is that the total magnetic moment of all ferromagnetic layers (12, 14, 16, 18) in the bottom reference layer stack 20 and all ferromagnetic layers (2, 4) in the bottom superlattice 110 having a parallel magnetization direction to the magnetization direction of the first barrier-contacting ferromagnetic layer 18 is greater than the total magnetic moment of all remaining ferromagnetic layers in the bottom superlattice 110 having an antiparallel magnetization direction to the magnetization direction of the first barrier-contacting ferromagnetic layer 18. Thus, a sum of (i) the magnetic moment of all ferromagnetic layers (12, 14, 16, 18) in the bottom reference layer stack 20, and (ii) the magnetic moments of all ferromagnetic component layers (2, 4) in the bottom superlattice 110 having a parallel magnetization direction to the magnetization direction of the first barrier-contacting ferromagnetic layer 18 is greater than and is antiparallel to the sum of the magnetic moments of all remaining ferromagnetic component layers (2, 4) in the bottom superlattice 110 having an antiparallel magnetization direction to the magnetization direction of the first barrier-contacting ferromagnetic layer 18.

In one embodiment, the bottom superlattice 110 may comprise a periodic repetition of four unit layer stacks 10. In this embodiment, the ferromagnetic component layers (2, 4) of the bottom and the second from the bottom unit layer stacks 10 have a magnetization direction that is parallel to the magnetization direction of the first barrier-contacting ferromagnetic layer 18. Furthermore, the ferromagnetic component layers (2, 4) of the first from the bottom and the third from the bottom unit layer stacks 10 have a magnetization direction that is antiparallel to the magnetization direction of the first barrier-contacting ferromagnetic layer 18. In this embodiment, the total magnetic moment of the first barrier-contacting ferromagnetic layer 18, the first proximal bottom ferromagnetic layer 16, the second proximal bottom ferromagnetic layer 14, the third proximal bottom ferromagnetic layer 12, and the ferromagnetic component layers (2, 4) of the bottom and the second from the bottom unit layer stacks 10 has a greater magnitude and an antiparallel direction relative to the total magnetic of the moment ferromagnetic component layers (2, 4) of the first from the bottom and the third from the bottom unit layer stacks 10.

Thus, in one embodiment, the barrier-contacting top ferromagnetic layer 68 comprises a portion of a top reference layer stack 160 located in the top SAF structure 190 and having a parallel magnetization direction to the magnetization direction of the barrier-contacting top ferromagnetic layer 68; and the barrier-contacting bottom ferromagnetic layer 18 comprises a portion of a bottom reference layer stack 20 located in the bottom SAF structure 120 and having a parallel magnetization direction to the magnetization direction of the barrier-contacting bottom ferromagnetic layer 18.

In one embodiment, the top SAF structure 190 further comprises a top hard magnetization structure (74, 170) having an antiparallel magnetization direction to the magnetization direction of the top reference layer stack 160, and a top antiferromagnetic coupling layer 65 located between the top hard magnetization structure (74, 170) and the top reference layer stack 160. The bottom SAF structure 120 further comprises a bottom superlattice 110 comprising a plurality of unit layer stacks 10 that each includes a first bottom ferromagnetic component layer 2, a bottom nonmagnetic component metal spacer layer 3, a second bottom ferromagnetic component layer 4, and a bottom antiferromagnetic coupling layer 5. Each odd numbered unit layer stack 10 in the bottom superlattice has a magnetization direction that is antiparallel to a magnetization direction of each even numbered unit layer stack 10 in the bottom superlattice 110; and the magnetization direction of the top reference layer stack 160 is antiparallel relative to the magnetization direction of the bottom reference layer stack 20.

In one embodiment, a magnetic moment of all ferromagnetic layers (66, 68) in the top reference layer stack 160 is less than a magnetic moment of all ferromagnetic layers (8, 74) in the top hard magnetization layer structure (74, 170). A total magnetic moment of all ferromagnetic layers (12, 14, 16, 18) in the bottom reference layer stack 20 and all ferromagnetic layers (2, 4) in the bottom superlattice 110 having a parallel magnetization direction to the magnetization direction of the barrier-contacting bottom ferromagnetic layer 18 is greater than a total magnetic moment of all remaining ferromagnetic layers (2, 4) in the bottom superlattice 110 having an antiparallel magnetization direction to the magnetization direction of the barrier-contacting bottom ferromagnetic layer 18. For example, a total magnetic moment of all ferromagnetic layers (12, 14, 16, 18) in the bottom reference layer stack 20 and all ferromagnetic layers (2, 4) in the bottom and second from the bottom unit layer stacks 10 of the bottom superlattice 110 having a parallel magnetization direction to the magnetization direction of the barrier-contacting bottom ferromagnetic layer 18 is greater than a total magnetic moment of all remaining ferromagnetic layers (2, 4) in the first and third from the bottom unit layer stacks 10 in the bottom superlattice 110 having an antiparallel magnetization direction to the magnetization direction of the barrier-contacting bottom ferromagnetic layer 18.

The synthetic antiferromagnet structures (120, 190) provide resilience to back-hopping, a phenomenon where the magnetization direction inadvertently reverses during the writing process, which can lead to data instability. The free layer 136 within the magnetoresistive memory cell 180 is designed to possess a high magnetic moment. Additionally, the free layer 136 exhibits strong perpendicular magnetic anisotropy, a property where the magnetic moments prefer to align perpendicularly to the plane of the layer, thereby, together with a high moment, enhancing the thermal stability of the magnetic state. The free layer 136 also has low magnetic damping, resulting in faster and more efficient switching.

The STT magnetoresistive memory cell 180 is programmed by flowing a write current between the first and second terminal electrodes (32, 92). The STT magnetoresistive memory cell 180 is read by flowing a read current having a lower value than the write current between the first and second terminal electrodes (32, 92).

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device comprising a magnetoresistive memory cell, wherein the magnetoresistive memory cell comprises:
a first terminal electrode;
a second terminal electrode; and
a double magnetic tunnel junction located between the first terminal electrode and the second terminal electrode, and comprising, from bottom to top, a bottom synthetic antiferromagnet (SAF) structure including a barrier-contacting bottom ferromagnetic layer, a first tunneling barrier layer, a common free layer, a second tunneling barrier layer, and a top SAF structure including a barrier-contacting top ferromagnetic layer in antiparallel alignment with the barrier-contacting bottom ferromagnetic layer, wherein the bottom SAF structure is different from the top SAF structure.

2. The memory device of claim 1, further comprising an ovonic threshold switch selector element located between the first terminal electrode and the second terminal electrode, and electrically in series with the double magnetic tunnel junction.

3. The memory device of claim 1, wherein:
the barrier-contacting top ferromagnetic layer comprises a portion of a top reference layer stack located in the top SAF structure and having a parallel magnetization direction to the magnetization direction of the barrier-contacting top ferromagnetic layer; and
the barrier-contacting bottom ferromagnetic layer comprises a portion of a bottom reference layer stack located in the bottom SAF structure and having a parallel magnetization direction to the magnetization direction of the barrier-contacting bottom ferromagnetic layer.

4. The memory device of claim 3, wherein:
the top SAF structure further comprises a top hard magnetization structure having an antiparallel magnetization direction to the magnetization direction of the top reference layer stack, and a top antiferromagnetic coupling layer located between the top hard magnetization structure and the top reference layer stack;
the bottom SAF structure further comprises a bottom superlattice comprising a plurality of unit layer stacks that each includes a first bottom ferromagnetic component layer, a bottom nonmagnetic component metal spacer layer, a second bottom ferromagnetic component layer, and a bottom antiferromagnetic coupling layer;
each odd numbered unit layer stack in the bottom superlattice has a magnetization direction that is antiparallel to a magnetization direction of each even numbered unit layer stack in the bottom superlattice; and
the magnetization direction of the top reference layer stack is antiparallel relative to the magnetization direction of the bottom reference layer stack.

5. The memory device of claim 4, wherein:
a magnetic moment of all ferromagnetic layers in the top reference layer stack is less than a magnetic moment of all ferromagnetic layers in the top hard magnetization layer structure; and
a total magnetic moment of all ferromagnetic layers bottom reference layer stack and all ferromagnetic layers in the bottom superlattice having a parallel magnetization direction to the magnetization direction of the barrier-contacting bottom ferromagnetic layer is greater than a total magnetic moment of all remaining ferromagnetic layers in the bottom superlattice having an antiparallel magnetization direction to the magnetization direction of the barrier-contacting bottom ferromagnetic layer.

6. The memory device of claim 5, wherein the top reference layer stack further comprises:
a proximal top ferromagnetic layer that overlies the barrier-contacting top ferromagnetic layer and has a parallel magnetization direction to the magnetization direction of the barrier-contacting top ferromagnetic layer; and
a nonmagnetic metal texture breaking layer located between the proximal top ferromagnetic layer and the barrier-contacting top ferromagnetic layer.

7. The memory device of claim 5, wherein:
the barrier-contacting bottom ferromagnetic layer, the common free layer, and the barrier-contacting top ferromagnetic layer comprise a first ferromagnetic material; and
the proximal top ferromagnetic layer comprises a second ferromagnetic material that is different from the first ferromagnetic material.

8. The memory device of claim 7, wherein:
the top hard magnetization structure comprises a topside ferromagnetic layer that overlies the proximal top ferromagnetic layer and that comprises the second ferromagnetic material; and
top superlattice of a unit layer stack that includes a top ferromagnetic component layer and a top nonmagnetic metal spacer layer; and
the top superlattice overlies the topside ferromagnetic layer.

9. The memory device of claim 8, wherein:
the barrier-contacting top ferromagnetic layer comprises CoFeB;
the proximal top ferromagnetic layer consists essentially of cobalt;
the topside ferromagnetic layer consists essentially of cobalt;
the top ferromagnetic component layer consists essentially of cobalt;
the top nonmagnetic metal spacer layer comprises platinum;
the top antiferromagnetic coupling layer comprises ruthenium; and
the nonmagnetic metal texture breaking layer comprises tungsten.

10. The memory device of claim 5, wherein:
the bottom superlattice comprises a periodic repetition of four unit layer stacks;
the first and the second ferromagnetic component layers of a bottom unit layer stack and of a second from the bottom unit layer stack have a magnetization direction that is parallel to the magnetization direction of the barrier-contacting bottom ferromagnetic layer; and
the first and the second ferromagnetic component layers of a first from the bottom unit layer stack and a third from the bottom unit layer stack have a magnetization direction that is antiparallel to the magnetization direction of the barrier-contacting bottom ferromagnetic layer.

11. The memory device of claim 10, wherein the total magnetic moment of the bottom reference layer stack and the first and the second ferromagnetic component layers of the bottom and the second from the bottom unit layer stacks has a greater magnitude and an antiparallel direction relative to the total magnetic moment of the first and the second ferromagnetic component layers of the first from the bottom and the third from the bottom unit layer stacks.

12. The memory device of claim 5, wherein the bottom reference layer stack further comprises at least one proximal bottom ferromagnetic layer located between the barrier-contacting bottom ferromagnetic layer and the bottom superlattice.

13. The memory device of claim 5, wherein the bottom reference layer stack further comprises
first, second, and third proximal bottom ferromagnetic layers located between the barrier-contacting bottom ferromagnetic layer and the bottom superlattice;
a first bottom nonmagnetic texture breaking layer located between the first proximal bottom ferromagnetic layer and the barrier-contacting bottom ferromagnetic layer;
a second bottom nonmagnetic texture breaking layer located between the first proximal bottom ferromagnetic layer and the second proximal bottom ferromagnetic layer; and
a bottom nonmagnetic metal spacer layer located between the second proximal bottom ferromagnetic layer and the third proximal bottom ferromagnetic layer.

14. The memory device of claim 13, wherein magnetization directions of the first, second, and third proximal bottom ferromagnetic layers are parallel to the magnetization direction of the barrier-contacting bottom ferromagnetic layer.

15. The memory device of claim 13, wherein the barrier-contacting bottom ferromagnetic layer and the first proximal bottom ferromagnetic layer comprise a first ferromagnetic material and the second and third proximal bottom ferromagnetic layers comprise a second ferromagnetic material different from the first ferromagnetic material.

16. The memory device of claim 15, wherein:
the first and second bottom ferromagnetic component layers consist essentially of cobalt;
the bottom nonmagnetic component metal spacer layer comprises platinum;
the bottom antiferromagnetic coupling layer comprises iridium;
the barrier-contacting bottom ferromagnetic layer and the first proximal bottom ferromagnetic layer comprise CoFeB;
the second and third proximal bottom ferromagnetic layers consist essentially of cobalt;
the first and second bottom nonmagnetic texture breaking layers comprise tungsten; and
the bottom nonmagnetic metal spacer layer comprises platinum.

17. The memory device of claim 15, wherein:
the top reference layer stack further comprises a proximal top ferromagnetic layer that overlies the barrier-contacting top ferromagnetic layer and has a parallel magnetization direction to the magnetization direction of the barrier-contacting top ferromagnetic layer, and a nonmagnetic metal texture breaking layer located between the proximal top ferromagnetic layer and the barrier-contacting top ferromagnetic layer; and
the top hard magnetization structure comprises a topside ferromagnetic layer that overlies the proximal top ferromagnetic layer, and a top superlattice of a unit layer stack that includes a top ferromagnetic component layer and a top nonmagnetic metal spacer layer.

18. The memory device of claim 17, wherein:
the barrier-contacting top ferromagnetic layer comprises CoFeB;
the proximal top ferromagnetic layer consists essentially of cobalt;
the topside ferromagnetic layer consists essentially of cobalt;
the top ferromagnetic component layer consists essentially of cobalt;
the top nonmagnetic metal spacer layer comprises platinum;
the top antiferromagnetic coupling layer comprises ruthenium; and
the nonmagnetic metal texture breaking layer comprises tungsten.

19. The memory device of claim 1, wherein the memory device comprises a spin-transfer torque (STT) magnetoresistive random access memory (MRAM) device.

20. A method of making a memory device, comprising:
forming a first terminal electrode over a substrate;
forming a double magnetic tunnel junction over the first terminal electrode by forming a bottom synthetic antiferromagnet (SAF) structure including a barrier-contacting bottom ferromagnetic layer over the first terminal electrode, forming a first tunneling barrier layer over the bottom SAF structure, forming a common free layer over the first tunneling barrier layer, forming a second tunneling barrier layer over common free layer, and forming a top SAF structure including a barrier-contacting top ferromagnetic layer over the second common free layer, wherein the barrier-contacting top ferromagnetic layer is formed in antiparallel alignment with the barrier-contacting bottom ferromagnetic layer without applying an external magnetic field; and
forming a second terminal electrode over the double magnetic tunnel junction.
